(19) United States
(12) Patent Application Publication
(10) Pub. No.: US 2026/0282639 A1
(43) Pub. Date: Sep. 17, 2026

(54) DISPLAY DEVICE HAVING LENS

(71) Applicant: LX Semicon Co.,Ltd., Daejeon (KR)

(72) Inventor: Jung Hoon KIM, Daejeon (KR)

(73) Assignee: LX Semicon Co.,Ltd., Daejeon (KR)

(21) Appl. No.: 19/563,727

(22) Filed: Mar. 11, 2026

(30) Foreign Application Priority Data
Mar. 12, 2025 (KR) 10-2025-0031795

(51) Int. Cl. H10H 29/855; H10H 29/32; H10H 29/39; H10H 29/80; H10H 29/854

(52) U.S. Cl. CPC H10H 29/855; H10H 29/32; H10H 29/39; H10H 29/854; H10H 29/962

(57) ABSTRACT

A display device having a lens can include a first planarization layer covering first, second and third thin film transistors disposed on a substrate, a first light-emitting element of connected to the first thin film transistor on the first planarization layer, a first micro-lens disposed on the first light-emitting element, a second planarization layer disposed on the first planarization layer and covering the first micro-lens and the first light-emitting element, a second light-emitting element connected to the second thin film transistor on the second planarization layer, a second micro-lens disposed on the second light-emitting element, a third planarization layer disposed on the second planarization layer and covering the second micro-lens and the second light-emitting element, a third light-emitting element connected to the third thin film transistor on the third planarization layer, and a third micro-lens disposed on the third light-emitting element.

### CROSS-REFERENCE TO RELATED APPLICATION

This application claims priority to and the benefit of Korean Patent Application No. 10-2025-0031795, filed Mar. 12, 2025, the disclosure of which is incorporated herein by reference in its entirety.

### BACKGROUND

### Field

The present specification relates to a display device having a lens.

### Discussion of Related Art

In general, in order to apply micro LED chips made of GaN or AlGaInP-based compounds to the AR/VR field, the screen door effect must be eliminated by reducing the display pixel size to solve eye fatigue and dizziness. For this purpose, a 5000 ppi high-resolution micro display may be implemented by stacking red/green/blue chips in a vertical direction to control the pixel size.

However, the vertically stacked micro-LED pixel structure inevitably causes color crosstalk depending on a position of a light source, which can lead to color separation phenomenon at pixel edges regardless of the viewing angle.

### SUMMARY

A problem to be solved according to an embodiment of the present specification is to provide a display device having a lens, which may improve display quality of the light-emitting element by improving optical efficiency of an ultra-high-resolution micro light-emitting element having a vertically stacked structure and by controlling color crosstalk.

The problems to be solved according to the embodiments of the present specification are not limited to the problems mentioned above, and other problems not mentioned will be clearly understood by those skilled in the art from the description below.

A display device according to the present specification includes: first, second and third thin film transistors disposed on a substrate; a first planarization layer disposed on the substrate and covering the first to the third thin film transistors; a first light-emitting element of a first color disposed on the first planarization layer and connected to the first thin film transistor; a first micro-lens disposed on the first light-emitting element; a second planarization layer disposed on the first planarization layer and covering the first micro-lens and the first light-emitting element; a second light-emitting element of a second color disposed on the second planarization layer and connected to the second thin film transistor; a second micro-lens disposed on the second light-emitting element; a third planarization layer disposed on the second planarization layer and covering the second micro-lens and the second light-emitting element; a third light-emitting element of a third color disposed on the third planarization layer and connected to the third thin film transistor; and a third micro-lens disposed on the third light-emitting element.

A curvature of the first micro-lens may be greater than a curvature of the second micro-lens, and the curvature of the second micro-lens may be greater than a curvature of the third micro-lens.

The first light-emitting element of the first color may be a red light-emitting element, the second light-emitting element of the second color may be a green light-emitting element, and the third light-emitting element of the third color may be a blue light-emitting element.

The first to the third light-emitting elements may be disposed to vertically overlap one another.

The first to the third micro-lenses may include a hemispherical shape.

The first micro-lens and the second micro-lens may include a cylindrical lens or a batwing lens.

A planar shape of the first micro-lens and the second micro-lens may include any one of a circular shape, a square shape, a hexagonal shape, and a polygonal shape.

The third micro-lens may include a hemispherical shape.

The first light-emitting element may be connected to the first thin film transistor through a first anode electrode disposed on the first planarization layer, the second light-emitting element may be connected to the second thin film transistor through a first connection electrode disposed on the first planarization layer and a second anode electrode disposed on the second planarization layer, and the third light-emitting element may be connected to the third thin film transistor through a first connection electrode disposed on the first planarization layer, a second connection electrode disposed on the second planarization layer, and a third anode electrode disposed on the third planarization layer.

The display device may further include a fourth planarization layer disposed on the third planarization layer and covering the third micro-lens and the third light-emitting element.

A first transparent resin encapsulant may be disposed between the first light-emitting element and the first micro-lens, a second transparent resin encapsulant may be disposed between the second light-emitting element and the second micro-lens, and a third transparent resin encapsulant may be disposed between the third light-emitting element and the third micro-lens.

Specific matters according to various examples of the present specification other than the means for solving the above-mentioned problems are included in the following description and drawings.

According to the present specification, by disposing micro-lenses having different radii of curvature on upper portions of the red/green/blue light-emitting elements of the vertically stacked structure, respectively, light obscured by the light-emitting elements and laterally emitted light may be minimized to improve optical efficiency and control color crosstalk.

According to the present specification, when a cylindrical lens is applied, light intensity at a central portion and an outer portion of the light-emitting elements may be controlled to minimize light lost, thereby controlling light obscured by an upper light-emitting element among a plurality of light-emitting elements stacked vertically.

According to the present specification, by enhancing light extraction while minimizing light obscured by the upper light-emitting element chip through the use of a lens, the light extraction efficiency of a micro LEDoS (LED on Silicon) pixel may be maximized.

The effects of the present specification are not limited to the effects mentioned above, and other effects not mentioned will be clearly understood by those having ordinary skill in the art to which the technical idea of the present specification pertains from the description below.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a schematic perspective view showing a display device having a lens according to an embodiment of the present specification;

FIG. 2 is an enlarged view of portion A of FIG. 1;

FIG. 3 is a cross-sectional view taken along line I-I′ of FIG. 1;

FIG. 4 is a view schematically showing first to third micro-lenses in a display device having a lens according to an embodiment of the present specification;

FIG. 5 is an enlarged view of portion A of FIG. 1 in a display device having a lens according to another embodiment of the present specification;

FIG. 6 is a cross-sectional view of a display device having a lens according to another embodiment of the present specification;

FIG. 7 is a view schematically showing first to third micro-lenses in a display device having a lens according to another embodiment of the present specification;

FIG. 8 are views showing planar shapes of first and second micro-lenses in a display device having a lens according to another embodiment of the present specification;

FIG. 9 is a view showing characteristics of first and second micro-lenses within a first sub-pixel in a display device having a lens according to another embodiment of the present specification;

FIG. 10 is a view showing characteristics of a third micro-lens in a display device having a lens according to another embodiment of the present specification;

FIG. 11 is a view schematically showing first to third micro-lenses in a display device having a lens according to still another embodiment of the present specification; and

FIG. 12 is a view showing characteristics of the first and second micro-lenses in the display device having lenses according to still another embodiment of the present specification.

### DETAILED DESCRIPTION OF EXEMPLARY EMBODIMENTS

The advantages and features of the present specification, and methods of achieving them will be apparent from the embodiments described in detail below in conjunction with the accompanying drawings. However, the present specification is not limited to the following embodiments disclosed herein, but may be implemented in various different forms; rather, the present embodiments are provided to make the disclosure complete and to fully convey the scope of the present specification to those skilled in the art.

The shapes, sizes, proportions, angles, numbers, and the like of elements shown in the drawings to illustrate embodiments of the present specification are merely illustrative and the present specification is not limited to the illustrated matters.

Identical reference numerals may designate identical components throughout the description. Further, in describing the present specification, detailed descriptions of related known technologies may be omitted so as not to obscure the essence of the present specification. The terms such as “including,” “having,” and “consisting of” as used herein are generally intended to allow other components to be added unless the terms are used with the term “only.” References to components of a singular noun include the plural of that noun, unless specifically stated otherwise.

In the interpretation of components, they are construed to include margins of error, even if not explicitly stated.

When describing a positional relationship, for example, “on,” “above,” “below,” “next to,” or “adjacent to” describes the positional relationship of two parts, one or more other parts may be located between the two parts, unless “immediately,” “directly,” or “near to” is used.

When describing a temporal relationship, “after,” “subsequently to,” “following,” or, “before” describes a temporal antecedent or consequent relationship, which may not be continuous unless “immediately,” or “directly” is used.

The first, the second, and so on are used to describe various components, but these components are not limited by these terms. These terms are used only to distinguish one component from another. Therefore, a first component referred to below may be a second component within the technical spirit of the present specification.

Terms such as first, second, A, B, (a), or (b) may be used to describe elements of the embodiments of the present specification. Such terms are intended only to distinguish one component from another and are not intended to define the nature, sequence, order, or number of such components.

When a component is described as being “connected,” “coupled”, “interfaced,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

When a component is described as being “in contact” or “overlapping” with another component, it is to be understood that the component may be in direct contact or overlap with the other component, but other components may also be “interposed” between these components, resulting in indirect contact or overlap, unless specifically stated otherwise.

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms “the first direction,” “the second direction,” “the third direction,” “the X-axis direction,” “the Y-axis direction,” and “the Z-axis direction” are not to be interpreted solely as a geometric relationship in which the relationship to one another is perpendicular, but may refer to a broader range of orientations in which the configurations of the present specification may function.

Each of the features of various embodiments of the present specification may be coupled or combined with one another in whole or in part, and may be technologically interlocked and operated in various ways, and each of the embodiments may be carried out independently or in conjunction with one another.

Hereinafter, various embodiments of the present specification will be described in detail with reference to the accompanying drawings.

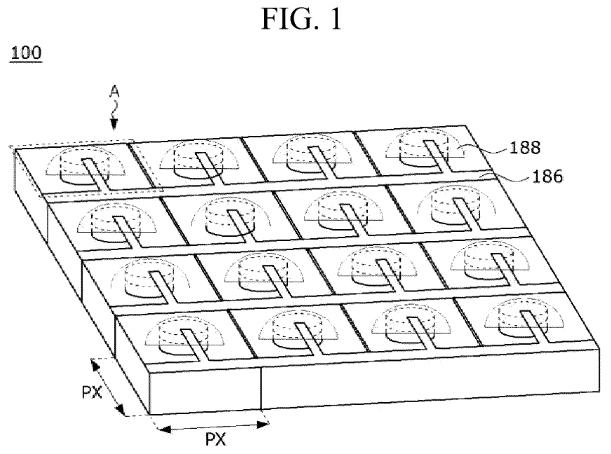

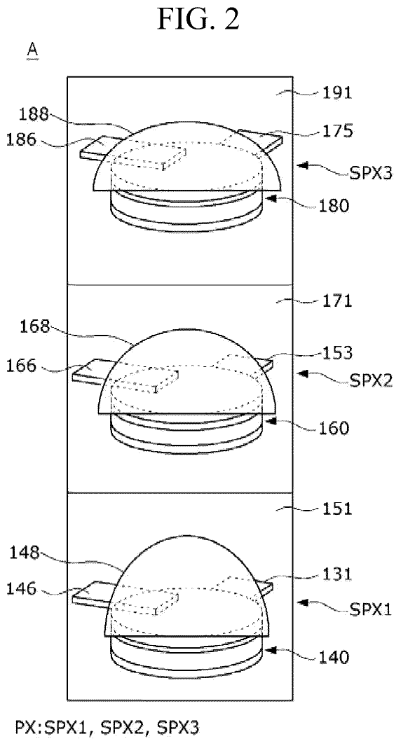

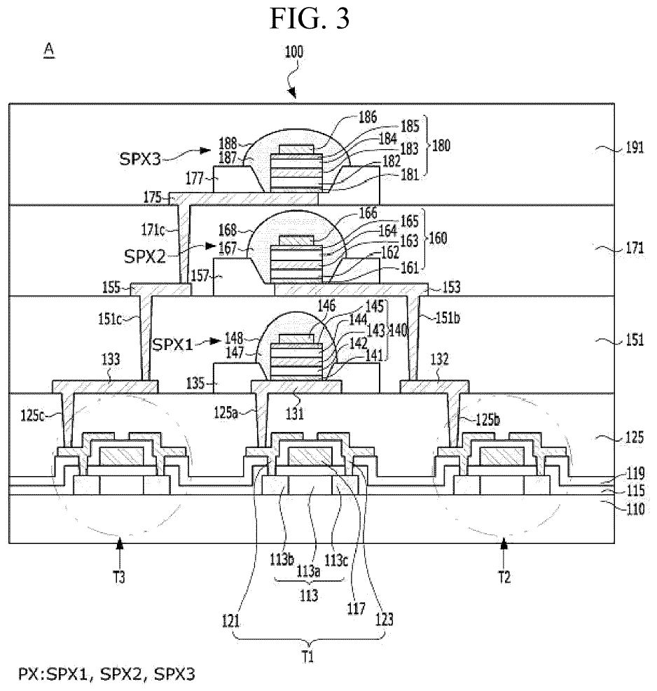

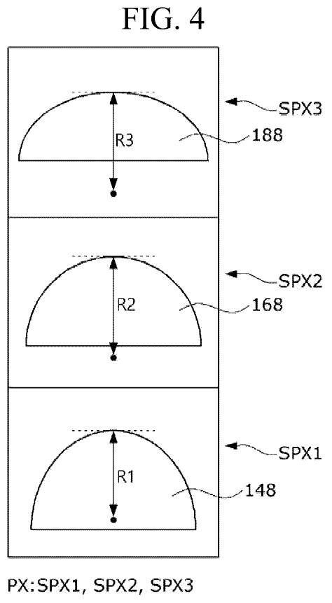

FIG. 1 is a schematic perspective view showing a display device having a lens according to an embodiment of the present specification. FIG. 2 is an enlarged view of portion A of FIG. 1. FIG. 3 is a cross-sectional view taken along line I-I′ of FIG. 1. FIG. 4 is a view schematically showing first to third micro-lenses in a display device having a lens according to an embodiment of the present specification.

Referring to FIGS. 1 to 4, pixels PX may be driven by a pixel driving circuit. The pixel driving circuit may receive a driving voltage, an image signal (digital signal), a synchronization signal synchronized with the image signal, and the like, and output an anode voltage and a cathode voltage of a light-emitting element to drive a plurality of pixels. The driving voltage may be a high potential voltage EVDD. The cathode voltage may be a low potential voltage EVSS applied in common to the pixels. The anode voltage may be a voltage corresponding to a pixel data value of the image signal.

Each of the pixels PX may include a plurality of sub-pixels SPX having different colors stacked vertically. For example, each of the plurality of pixels PX may be vertically stacked and may include a first sub-pixel SPX1 in which a first light-emitting element 140 emitting light of a red wavelength is disposed, a second sub-pixel SPX2 in which a second light-emitting element 160 emitting light of a green wavelength is disposed, and a third sub-pixel SPX3 in which a third light-emitting element 180 emitting light of a blue wavelength is disposed.

For example, a first signal wire may be connected to a first anode electrode 131 of the first sub-pixel SPX1, a second signal wire may be connected to a second anode electrode 153 of the second sub-pixel SPX2, and a third signal wire may be connected to a third anode electrode 175 of the third sub-pixel SPX3.

Also, first to third cathode electrodes 146, 166, and 186 may be a cathode electrode disposed one per row and configured to apply a cathode voltage to the first to the third light-emitting elements 140, 160, and 180 provided in the plurality of pixels PX vertically stacked continuously in a first direction (X-axis direction).

Specifically, the first cathode electrode 146 may be a cathode electrode disposed one per row and configured to apply a cathode voltage to the first light-emitting elements 140 provided in the plurality of pixels PX vertically stacked in the first direction.

Also, the second cathode electrode 166 may be a cathode electrode disposed one per row and configured to apply a cathode voltage to the second light-emitting elements 160 provided in the plurality of pixels PX vertically stacked in the first direction.

The third cathode electrode 186 may be a cathode electrode disposed one per row and configured to apply a cathode voltage to the third light-emitting elements 180 provided in the plurality of pixels PX vertically stacked in the first direction.

The first to the third cathode electrodes 146, 166, and 186 may be electrically connected to first-second, second-second and third-second contact electrodes 145, 165, and 185. However, the present specification is not necessarily limited thereto.

Referring to FIG. 3, in a display device 100 having a vertically stacked structure according to an embodiment of the present specification, a plurality of first, second and third anode electrodes 131, 153, and 175 may be vertically stacked above a substrate 110.

A plurality of first, second and third light-emitting elements 140, 160, and 180 may be vertically stacked on the plurality of first, second and third anode electrodes 131, 153, and 175, respectively.

Also, first, second and third transparent resin encapsulants 147, 167, and 187 covering the plurality of first, second and third light-emitting elements 140, 160, and 180 may be disposed on upper portions of the plurality of first, second and third light-emitting elements 140, 160, and 180.

First, second and third micro-lenses 148, 168, and 188 positioned on the upper portions of the plurality of first, second and third light-emitting elements 140, 160, and 180 may be disposed on the first, second and third transparent resin encapsulants 147, 167, and 187, respectively.

Here, the substrate 110 may be made of plastic having flexibility. For example, the substrate 110 may be manufactured as a single-layer or multi-layer substrate of a material selected from polyimide, polyethylene terephthalate, polyethylene naphthalate, polycarbonate, polyethersulfone, polyarylate, polysulfone, and cyclic-olefin copolymer, but is not limited thereto. For example, the substrate 110 may be a ceramic substrate or a glass substrate. In another embodiment, the substrate 110 may be a Si substrate. Other exemplary substrates may include GaAs, GaP, InP, SiC, ZnO, and sapphire substrates. However, the present specification is not limited thereto.

Referring to FIG. 3, a pixel driving circuit (not shown) may be disposed on the substrate 110 in a display area. The pixel driving circuit may include a plurality of thin film transistors formed using an amorphous silicon semiconductor, a polycrystalline silicon semiconductor, or an oxide semiconductor, for example, first to third thin film transistors T1, T2, and T3. Each of the first to the third thin film transistors T1, T2, and T3 may be respectively connected to the first, second and third light-emitting elements 140, 160, and 180 that are disposed vertically stacked.

The pixel driving circuit may include at least one driving thin film transistor, at least one switching thin film transistor, and at least one storage capacitor. When the pixel driving circuit includes a plurality of thin film transistors, they may be formed by a TFT (Thin Film Transistor) manufacturing process on the substrate 110. In an embodiment, the pixel driving circuit may be a concept collectively referring to a plurality of thin film transistors electrically connected to the first to the third light-emitting elements 140, 160, and 180.

The pixel driving circuit may be a driving driver manufactured using a MOSFET (Metal-oxide-silicon field effect transistor) manufacturing process on a single crystal semiconductor substrate 110. The driving driver may include a plurality of pixel driving circuits to drive the plurality of sub-pixels. When the pixel driving circuit is implemented as a driving driver, after an adhesive layer is disposed on the substrate 110, the driving driver may be mounted on the adhesive layer by a transfer process.

The first, second and third thin film transistors T1, T2, and T3 including an active layer 113, a gate electrode 117, a drain electrode 121, and a source electrode 123 may be disposed on the substrate 110. An active layer 113 may include a channel region 113a, a drain region 113b, and a source region 113c.

The first, second and third thin film transistors T1, T2, and T3 may be disposed for each of the plurality of pixels PX. Each of the plurality of pixels PX may include first, second and third sub-pixels SPX1, SPX2, and SPX3. In this case, the first, second and third thin film transistors T1, T2, and T3 may be respectively connected to the first, second and third sub-pixels SPX1, SPX2, and SPX3 constituting each of the pixels PX. Specifically, the first, second and third thin film transistors T1, T2, and T3 may be connected to the first, second and third light-emitting elements 140, 160, and 180 provided in the first, second and third sub-pixels SPX1, SPX2, and SPX3, respectively.

For convenience of explanation, only the driving thin film transistor among various thin film transistors that may be included in the display device 100 is illustrated in the drawings.

In addition, although the drawings exemplarily illustrate that the thin film transistor has a coplanar structure, the present specification is not limited thereto, and a thin film transistor having an inverted staggered structure may also be used. For example, an active layer 113 may be disposed on the substrate 110, and a gate insulating layer 115 for insulating the active layer 113 and the gate electrode 117 may be disposed on the active layer 113. The active layer 113 may include a channel region 113a, and a drain region 113b and a source region 113c on both sides of the channel region 113a.

Also, an interlayer insulating layer 119 for insulating the gate electrode 117 from the drain electrode 121 and the source electrode 123 may be disposed on the substrate 110.

The drain electrode 121 and the source electrode 123 respectively contacting the drain region 113b and the source region 113c of the active layer 113 may be formed on the interlayer insulating layer 119. In this case, the drain electrode 121 and the source electrode 123 may be respectively connected to the drain region 113b and the source region 113c through a drain region contact hole (not shown) and a source region contact hole (not shown) provided in the interlayer insulating layer 119 and the gate insulating layer 115.

Further, a first planarization layer 125 may be disposed on the first, second, and third thin film transistors T1, T2, and T3. The first planarization layer 125 may planarize upper portions of the first, second, and third thin film transistors T1, T2, and T3. The first planarization layer 125 may include a first contact hole 125a for electrically connecting between the first thin film transistor T1 constituting the first sub-pixel SPX1 among the vertically stacked first to third sub-pixels SPX1, SPX2, and SPX3 and the first anode electrode 131 of the first light-emitting element 140.

In addition, in the first planarization layer 125, a second contact hole 125b may be provided so that a second connection electrode 132 connected to the second anode electrode 153 of the second light-emitting element 160, which constitutes the second sub-pixel SPX2 and is vertically disposed above the first light-emitting element 140, contacts the second thin film transistor T2.

In addition, a third contact hole 125c may be provided in the first planarization layer 125 so that a third-first connection electrode 133 contacts the third thin film transistor T3, the third-first connection electrode 133 being in contact with the third-second connection electrode 155 connected to the third anode electrode 175 of the third light-emitting element 180 that constitutes the third sub-pixel SPX3 vertically disposed above the second light-emitting element 160.

Additionally, on the first planarization layer 125, through the respective first, second and third contact holes 125a, 125b, and 125c, the first anode electrode 131 connected to the first thin film transistor T1, and the second connection electrode 132 and the third-first connection electrode 133 respectively connected to the second and third thin film transistors T2 and T3 may be disposed.

The first anode electrode 131 may be disposed to correspond to each of a plurality of sub-pixels SPX1, SPX2, and SPX3 that are vertically disposed. The first anode electrode 131 may be formed of a conductive material having a high work function as a component for supplying holes to a first light-emitting layer 143. The first anode electrode 131 may be a transparent conductive layer formed of a transparent conductive oxide (TCO). For example, the first anode electrode 131 may be formed of one or more materials selected from transparent conductive oxides such as indium-tin-oxide (ITO), indium-zinc-oxide (IZO), indium-tin-zinc oxide (ITZO), tin oxide (SnO₂), zinc oxide (ZnO), indium-copper-oxide (ICO), and aluminum-doped zinc oxide (Al-doped ZnO (AZO)), but is not limited thereto.

When the display device 100 is driven in a top emission type, the anode electrode 131 may further include a reflective pattern to reflect light emitted from the first light-emitting layer 143 toward the first cathode electrode 146. The first anode electrode 131 may be formed separately for each of the first sub-pixel SPX1, the second sub-pixel SPX2, and the third sub-pixel SPX3.

In addition, a first bank pattern 135 may be disposed on an edge portion of the first anode electrode 131 and on the first planarization layer 125. Here, the first bank pattern 135 may partition a plurality of first light-emitting elements 140. The first bank pattern 135 may be made of an insulating material to insulate the first anode electrodes 131 of adjacent first sub-pixels SPX1 from each other. Also, the first bank pattern 135 may be configured as a black bank having high light absorptivity to prevent color mixing between the adjacent first sub-pixels SPX1. For example, the first bank pattern 135 may be made of polyimide resin, acrylic resin, or benzocyclobutene resin, but is not limited thereto.

The first light-emitting element 140 may be disposed on the first anode electrode 131 between the first bank patterns 135.

Here, the first light-emitting element 140 may include a first-first conductive semiconductor layer 142, a first light-emitting layer 143 disposed on the first-first conductive semiconductor layer 142, and a first-second conductive semiconductor layer 144 disposed on the first light-emitting layer 143. A first-first contact electrode 141 may be disposed under the first-first conductive semiconductor layer 142, and a first-second contact electrode 145 may be disposed on the upper portion of the first-second conductive semiconductor layer 144.

The first light-emitting element 140 may be formed on a silicon wafer using a method such as Metal Organic Chemical Vapor Deposition (MOCVD), Chemical Vapor Deposition (CVD), Plasma-Enhanced Chemical Vapor Deposition (PECVD), Molecular Beam Epitaxy (MBE), Hydride Vapor Phase Epitaxy (HVPE), or sputtering.

The first-first conductive semiconductor layer 142 may be implemented as a compound semiconductor such as group III-V or group II-VI, and may be doped with a first dopant. The first-first conductive semiconductor layer 142 may be formed of one or more of a semiconductor material having a composition formula of Alₓ₁In_{y1}Ga_{(1-x1-y1)}N (0≤x1≤1, 0≤y1≤1, 0≤x1+y1≤1), InAlGaN, AlGaAs, GaP, GaAs, GaAsP, or AlGaInP, but is not limited thereto. When the first dopant is an n-type dopant such as Si, Ge, Sn, Se, or Te, the first-first conductive semiconductor layer 142 may be an n-type nitride semiconductor layer. However, when the first dopant is a p-type dopant, the first-first conductive semiconductor layer 142 may be a p-type nitride semiconductor layer.

The first light-emitting layer 143 is a layer where electrons (or holes) injected through the first-first conductive semiconductor layer 142 and holes (or electrons) injected through the first-second conductive semiconductor layer 144 meet. The first light-emitting layer 143 may transition to a lower energy level as the electrons and holes recombine, and generate light having a wavelength corresponding thereto.

The first light-emitting layer 143 may have any one structure of a single well structure, a multi-well structure, a single quantum well structure, a multi-quantum well (MQW) structure, a quantum dot structure, or a quantum wire structure, and the structure of the first light-emitting layer 143 is not limited thereto. The first light-emitting layer 143 may generate light in a visible light wavelength range. For example, the first light-emitting layer 143 may output light in any one wavelength range of blue, green, and red. For example, the first light-emitting layer 143 in the present specification may output red light in a red wavelength range as an example.

The first-second conductive semiconductor layer 144 may be disposed on the first light-emitting layer 143. The first-second conductive semiconductor layer 144 may be implemented as a compound semiconductor such as group III-V or group II-VI, and the first-second conductive semiconductor layer 144 may be doped with a second dopant. The first-second conductive semiconductor layer 144 may be formed of a semiconductor material having a composition formula of Inₓ₂Al_{y2}Ga_{(1-x2-y2)}N (0≤x2≤1, 0≤y2≤1, 0≤x2+y2≤1) or a material selected from AlInN, AlGaAs, GaP, GaAs, GaAsP, or AlGaInP. When the second dopant is a p-type dopant such as Mg, Zn, Ca, Sr, or Ba, the first-second conductive semiconductor layer 144 doped with the second dopant may be a p-type semiconductor layer. When the second dopant is an n-type dopant, the first-second conductive semiconductor layer 144 may be an n-type nitride semiconductor layer.

In addition, the first cathode electrode 146 may be disposed on the first-second contact electrode 145 disposed on the first-second conductive semiconductor layer 144. In this case, the first cathode electrode 146 may be a cathode electrode disposed one per row and configured to apply a cathode voltage to the first light-emitting elements 140 provided in a plurality of pixels PX vertically stacked in a first direction.

Here, the first cathode electrode 146 may be composed of a transparent conductive material so that light emitted from the first light-emitting element 140 may be directed toward an upper side of the first light-emitting element 140, but embodiments of the present specification are not limited thereto. For example, the first cathode electrode 146 may be composed of a material such as indium tin oxide (ITO), indium zinc oxide (IZO), or indium gallium zinc oxide (IGZO), but embodiments of the present specification are not limited thereto.

The first transparent resin encapsulant 147 covering the first light-emitting element 140 may be disposed on the first bank pattern 135.

Referring to FIG. 4, the first micro-lens 148 having a first curvature K1 may be disposed on the first transparent resin encapsulant 147. The first micro-lens 148 may be formed using one selected from an organic material or an inorganic material. Specifically, the first micro-lens 148 may be made of a material having a refractive index close to a range of about 2.0 to 4.0, which is similar to micro-lens constituent materials such as GaN or AlGaInP. In addition, the peripheral portion of the first micro-lens may have a low refractive index, thereby increasing light extraction efficiency of the light-emitting element, and conversely, minimizing light entering the light-emitting element from the outside.

In addition, the first micro-lens 148 may have a hemispherical shape. However, the present specification is not limited thereto. The first curvature K1 may be 1/R1. Here, R1 may be a radius of the first micro-lens 148.

A second planarization layer 151 covering the first micro-lens 148, the first bank pattern 135, the second connection electrode 132, and the third-first connection electrode 133 may be disposed on the first planarization layer 125.

In the second planarization layer 151, a second anode contact hole 151b may be provided so that the second anode electrode 153 connected to the second light-emitting element 160 vertically disposed above the first light-emitting element 140 contacts the second connection electrode 132.

In addition, in the second planarization layer 151, a third connection electrode contact hole 151c may be provided so that the third-second connection electrode 155 in contact with the third anode electrode 175 connected to the third light-emitting element 180 vertically disposed above the second light-emitting element 160 contacts the third thin film transistor T3 through the third-first connection electrode 133.

On the second planarization layer 151, the second anode electrode 153 connected to the second thin film transistor T2 and the third-second connection electrode 155 connected to the third-first connection electrode 133 may be disposed, the third-first connection electrode 133 being connected to the third thin film transistor T3.

The second anode electrode 153 may be disposed to correspond respectively to each of a plurality of sub-pixels SPX1, SPX2, and SPX3 that are vertically disposed.

The second anode electrode 153 may be formed of a conductive material having a high work function as a component for supplying holes to the second light-emitting layer 163. The second anode electrode 153 may be a transparent conductive layer formed of a transparent conductive oxide (TCO). For example, the second anode electrode 153 may be formed of one or more materials selected from transparent conductive oxides such as indium-tin-oxide (ITO), indium-zinc-oxide (IZO), indium-tin-zinc oxide (ITZO), tin oxide (SnO2), zinc oxide (ZnO), indium-copper-oxide (ICO), and aluminum-doped zinc oxide (Al-doped ZnO (AZO)), but is not limited thereto.

In addition, a second bank pattern 157 may be disposed on an edge portion of the second anode electrode 153 and on the second planarization layer 151. Here, the second bank pattern 157 may partition a plurality of second light-emitting elements 160. The second bank pattern 157 may be made of an insulating material to insulate the second anode electrodes 153 of adjacent second sub-pixels SPX2 from each other. Also, the second bank pattern 157 may be configured as a black bank having high light absorptivity to prevent color mixing between the adjacent second sub-pixels SPX2. For example, the second bank pattern 157 may be made of polyimide resin, acrylic resin, or benzocyclobutene resin, but is not limited thereto.

For example, the second bank pattern 157 may be made of an organic insulating material. The second bank pattern 157 may be composed of a single-layer or multi-layer of an organic insulating material. For example, the second bank pattern 157 may be composed of photoresist, polyimide (PI), or acrylic material, but embodiments of the present specification are not limited thereto.

The second light-emitting element 160 may be disposed on the second anode electrode 153 between the second bank patterns 157.

Here, the second light-emitting element 160 may include a second-first conductive semiconductor layer 162, a second light-emitting layer 163 disposed on the second-first conductive semiconductor layer 162, and a second-second conductive semiconductor layer 164 disposed on the second light-emitting layer 163. A second-first contact electrode 161 may be disposed under the second-first conductive semiconductor layer 162, and a second-second contact electrode 165 may be disposed on the second-second conductive semiconductor layer 164.

The second light-emitting element 160 may be formed on a silicon wafer using a method such as Metal Organic Chemical Vapor Deposition (MOCVD), Chemical Vapor Deposition (CVD), Plasma-Enhanced Chemical Vapor Deposition (PECVD), Molecular Beam Epitaxy (MBE), Hydride Vapor Phase Epitaxy (HVPE), or sputtering.

The second-first conductive semiconductor layer 162 may be implemented as a compound semiconductor such as group III-V or group II-VI, and may be doped with a first dopant. The second-first conductive semiconductor layer 162 may be formed of one or more of a semiconductor material having a composition formula of Alₓ₁In_{y1}Ga_{(1-x1-y1)}N (0≤x1≤1, 0≤y1≤1, 0≤x1+y1≤1), InAlGaN, AlGaAs, GaP, GaAs, GaAsP, or AlGaInP, but is not limited thereto. When the first dopant is an n-type dopant such as Si, Ge, Sn, Se, or Te, the second-first conductive semiconductor layer 162 may be an n-type nitride semiconductor layer. However, when the first dopant is a p-type dopant, the second-first conductive semiconductor layer 162 may be a p-type nitride semiconductor layer.

The second light-emitting layer 163 is a layer where electrons (or holes) injected through the second-first conductive semiconductor layer 162 and holes (or electrons) injected through the second-second conductive semiconductor layer 164 meet. The second light-emitting layer 163 may transition to a lower energy level as the electrons and holes recombine, and generate light having a wavelength corresponding thereto.

The second light-emitting layer 163 may have any one structure of a single well structure, a multi-well structure, a single quantum well structure, a multi-quantum well (MQW) structure, a quantum dot structure, or a quantum wire structure, and the structure of the second light-emitting layer 163 is not limited thereto. The second light-emitting layer 163 may generate light in a visible light wavelength range. For example, the second light-emitting layer 163 may output light in any one wavelength range of blue, green, and red. For example, in the present embodiment, the second light-emitting layer 163 may output green light in a green wavelength range as an example.

The second-second conductive semiconductor layer 164 may be disposed on the second light-emitting layer 163. The second-second conductive semiconductor layer 164 may be implemented as a compound semiconductor such as group III-V or group II-VI, and the second-second conductive semiconductor layer 164 may be doped with a second dopant. The second-second conductive semiconductor layer 164 may be formed of a semiconductor material having a composition formula of Inₓ₂Al_{y2}Ga_{(1-x2-y2)}N (0≤x2≤1, 0≤y2≤1, 0≤x2+y2≤1) or a material selected from AlInN, AlGaAs, GaP, GaAs, GaAsP, or AlGaInP. When the second dopant is a p-type dopant such as Mg, Zn, Ca, Sr, or Ba, the second-second conductive semiconductor layer 164 doped with the second dopant may be a p-type semiconductor layer. When the second dopant is an n-type dopant, the second-second conductive semiconductor layer 164 may be an n-type nitride semiconductor layer.

In addition, the second cathode electrode 166 may be disposed on the second-second contact electrode 165 disposed on the second-second conductive semiconductor layer 164. In this case, the second cathode electrode 166 may be a cathode electrode disposed one per row and configured to apply a cathode voltage to the second light-emitting elements 160 provided in a plurality of pixels PX vertically stacked in the first direction.

Here, the second cathode electrode 166 may be composed of a transparent conductive material so that light emitted from the second light-emitting element 160 may be directed toward an upper side of the second light-emitting element 160, but embodiments of the present specification are not limited thereto. For example, the second cathode electrode 166 may be composed of a material such as indium tin oxide (ITO), indium zinc oxide (IZO), or indium gallium zinc oxide (IGZO), but embodiments of the present specification are not limited thereto.

The second transparent resin encapsulant 167 covering the second light-emitting element 160 may be disposed on the second bank pattern 157.

In addition, the second micro-lens 168 having a second curvature K2 may be disposed on the second transparent resin encapsulant 167. Here, the second micro-lens 168 may be formed using one selected from an organic material or an inorganic material. Specifically, the second micro-lens 168 may be made of a material having a refractive index close to a range of about 2.0 to 4.0, which is similar to micro-lens constituent materials such as GaN or AlGaInP. In addition, the peripheral portion of the second micro-lens 168 may have a low refractive index, thereby increasing light extraction efficiency of the light-emitting element, and conversely, minimizing light entering the light-emitting element from the outside.

In addition, the second micro-lens 168 may have a hemispherical shape. However, the present specification is not limited thereto. Also, the second curvature K2 may be 1/R2. Here, R2 may be a radius of the second micro-lens 168. Also, the second curvature K2 may be less than the first curvature K1.

A third planarization layer 171 covering the second micro-lens 168, the second bank pattern 157, the second anode electrode 153, and the third-second connection electrode 155 may be disposed on the second planarization layer 151.

In addition, in the third planarization layer 171, a third anode contact hole 171c may be provided so that the third anode electrode 175 connected to the third light-emitting element 180 vertically disposed above the second light-emitting element 160 contacts the third-second connection electrode 155.

On the third planarization layer 171, the third anode electrode 175 connected to the third-first connection electrode 133 and the third-second connection electrode 155 may be disposed, the third-first connection electrode 133 being in contact with the third thin film transistor T3 through the third anode contact hole 171c, and the third-second connection electrode 155 being connected to the third-first connection electrode 133.

Here, the third anode electrode 175 may be disposed in correspondence with each of a plurality of first, second, and third sub-pixels SPX1, SPX2, and SPX3 that are vertically disposed. The third anode electrode 175 may be formed of a conductive material having a high work function as a component for supplying holes to the third light-emitting layer 183. The third anode electrode 175 may be a transparent conductive layer formed of a transparent conductive oxide (TCO). For example, the third anode electrode 175 may be formed of one or more materials selected from transparent conductive oxides such as indium-tin-oxide (ITO), indium-zinc-oxide (IZO), indium-tin-zinc oxide (ITZO), tin oxide (SnO2), zinc oxide (ZnO), indium-copper-oxide (ICO), and aluminum-doped zinc oxide (Al-doped ZnO, AZO), but is not limited thereto.

In addition, a third bank pattern 177 may be disposed on an edge portion of the third anode electrode 175 and on the third planarization layer 171. Here, the third bank pattern 177 may partition a plurality of third light-emitting elements 180. The third bank pattern 177 may be made of an insulating material to insulate the third anode electrodes 175 of adjacent third sub-pixels SPX3 from each other. In addition, the third bank pattern 177 may be configured as a black bank having high light absorptivity to prevent color mixing between adjacent third sub-pixels SPX3. For example, the third bank pattern 177 may be made of polyimide resin, acrylic resin, or benzocyclobutene resin, but is not limited thereto.

A third light-emitting element 180 may be disposed on the third anode electrode 175 between the third bank patterns 177.

Here, the third light-emitting element 180 may include a third-first conductive semiconductor layer 182, a third light-emitting layer 183 disposed on the third-first conductive semiconductor layer 182, and a third-second conductive semiconductor layer 184 disposed on the third light-emitting layer 183. A third-first contact electrode 181 may be disposed under the third-first conductive semiconductor layer 182, and a third-second contact electrode 185 may be disposed on the third-second conductive semiconductor layer 184.

The third light-emitting element 180 may be formed on a silicon wafer using methods such as Metal Organic Chemical Vapor Deposition (MOCVD), Chemical Vapor Deposition (CVD), Plasma-Enhanced Chemical Vapor Deposition (PECVD), Molecular Beam Epitaxy (MBE), Hydride Vapor Phase Epitaxy (HVPE), or sputtering.

The third-first conductive semiconductor layer 182 may be implemented as a compound semiconductor such as group III-V or group II-VI, and may be doped with a first dopant. The third-first conductive semiconductor layer 182 may be formed of one or more of a semiconductor material having a composition formula of Alₓ₁In_{y1}Ga_{(1-x1-y1)}N (0≤x1≤1, 0≤y1≤1, 0≤x1+y1≤1), InAlGaN, AlGaAs, GaP, GaAs, GaAsP, or AlGaInP, but is not limited thereto. When the first dopant is an n-type dopant such as Si, Ge, Sn, Se, or Te, the third-first conductive semiconductor layer 182 may be an n-type nitride semiconductor layer. However, when the first dopant is a p-type dopant, the third-first conductive semiconductor layer 182 may be a p-type nitride semiconductor layer.

The third light-emitting layer 183 is a layer where electrons (or holes) injected through the third-first conductive semiconductor layer 182 and holes (or electrons) injected through the third-second conductive semiconductor layer 184 meet. The third light-emitting layer 183 may transition to a lower energy level as the electrons and holes recombine, and generate light having a wavelength corresponding thereto.

The third light-emitting layer 183 may have any one structure of a single well structure, a multi-well structure, a single quantum well structure, a multi-quantum well (MQW) structure, a quantum dot structure, or a quantum wire structure, and the structure of the third light-emitting layer 183 is not limited thereto. The third light-emitting layer 183 may generate light in a visible light wavelength range. For example, the third light-emitting layer 183 may output light in any one wavelength range of blue, green, and red. For example, in the present embodiment, the third light-emitting layer 183 may output blue light in a blue wavelength range as an example.

The third-second conductive semiconductor layer 184 may be disposed on the third light-emitting layer 183. The third-second conductive semiconductor layer 184 may be implemented as a compound semiconductor such as group III-V or group II-VI, and the third-second conductive semiconductor layer 184 may be doped with a second dopant. The third-second conductive semiconductor layer 184 may be formed of a semiconductor material having a composition formula of Inₓ₂Al_{y2}Ga_{(1-x2-y2)}N(0≤x2≤1, 0≤y2≤1, 0≤x2+y2≤1) or a material selected from AlInN, AlGaAs, GaP, GaAs, GaAsP, or AlGaInP. When the second dopant is a p-type dopant such as Mg, Zn, Ca, Sr, or Ba, the third-second conductive semiconductor layer 184 doped with the second dopant may be a p-type semiconductor layer. When the second dopant is an n-type dopant, the third-second conductive semiconductor layer 184 may be an n-type nitride semiconductor layer.

In addition, the third cathode electrode 186 may be disposed on the third-second contact electrode 185 disposed on the third-second conductive semiconductor layer 184. In this case, the third cathode electrode 186 may be a cathode electrode disposed one per row and configured to apply a cathode voltage to the third light-emitting elements 180 provided in a plurality of pixels PX vertically stacked in the first direction.

Here, the third cathode electrode 186 may be composed of a transparent conductive material so that light emitted from the third light-emitting element 180 may be directed toward an upper side of the third light-emitting element 180, but embodiments of the present specification are not limited thereto. For example, the third cathode electrode 186 may be composed of a material such as indium tin oxide (ITO), indium zinc oxide (IZO), or indium gallium zinc oxide (IGZO), but embodiments of the present specification are not limited thereto.

A third transparent resin encapsulant 187 covering the third light-emitting element 180 may be disposed on the third bank pattern 177.

In addition, the third micro-lens 188 having a third curvature K3 may be disposed on the third transparent resin encapsulant 187. The third micro-lens 188 may be formed using one selected from an organic material or an inorganic material. Specifically, the third micro-lens 188 may be made of a material having a refractive index close to a range of about 2.0 to 4.0, which is similar to micro-lens constituent materials such as GaN or AlGaInP. In addition, the peripheral portion of the third micro-lens 188 may have a low refractive index, thereby increasing light extraction efficiency of the light-emitting element, and conversely, minimizing light entering the light-emitting element from the outside.

Here, the third micro-lens 188 may have a hemispherical shape. However, the present specification is not limited thereto. In addition, the third curvature K3 may be 1/R3. Here, R3 may be a radius of the third micro-lens 188. The third curvature K3 may be less than each of the first curvature K1 and the second curvature K2.

A fourth planarization layer 191 covering the third micro-lens 188, the third bank pattern 177, and the third anode electrode 175 may be disposed on the third planarization layer 171.

Referring to FIGS. 3 and 4, the first micro-lens 148 may be disposed to overlap with an upper side of the first light-emitting element 140. Also, the second micro-lens 168 may be disposed to overlap with an upper side of the second light-emitting element 160. The third micro-lens 188 may be disposed to overlap with an upper side of the third light-emitting element 180.

Here, the hemispherical first, second, and third micro-lenses 148, 168, and 188 may have first, second, and third radii R1, R2, and R3.

Additionally, in the first, second, and third micro-lenses 148, 168, and 188, a curvature K may be represented as 1/radius R.

Therefore, curvatures K1, K2, and K3 of the first, second, and third micro-lenses 148, 168, and 188 may be represented as following Equation (1):

K1>K2>K3 Equation (1)

In Equation, K1 represents a first curvature of the first micro-lens 148, K2 represents a second curvature of the second micro-lens 168, and K3 represents a third curvature of the third micro-lens 188.

As shown in Equation (1), the curvatures K1, K2, and K3 of the first, second, and third micro-lenses 148, 168, and 188 may be different from each other. Specifically, the first curvature K1 of the first micro-lens 148 positioned on the first light-emitting element 140, which is a red sub-pixel SPX1 located at a lowermost layer, may be the largest. Also, the third curvature K3 of the third micro-lens 188 positioned on the third light-emitting element 180, which is a blue sub-pixel SPX3 located at a top layer, may be the smallest. In other words, when micro-lenses having different curvatures K is applied, the light path may be altered, and as the curvature K increases, the straightness of the light path may become more predominant.

Therefore, according to an embodiment of the present specification, by disposing micro-lenses 148, 168, and 188 having different curvatures K on upper portions of the respective first to third light-emitting elements 140, 160, and 180 arranged to be vertically stacked, the light paths extracted from the first to third light-emitting elements 140, 160, and 180 may be altered.

Moreover, according to an embodiment of the present specification, by disposing the first micro-lens 148 having the largest curvature K on the first light-emitting element 140 located at the lowermost position, straightness of light becomes predominant, thereby effectively controlling color crosstalk phenomenon due to the positions of not only the first light-emitting element 140, which is the lowermost red light-emitting element, but also the second light-emitting element 160, which is the middle green light-emitting element.

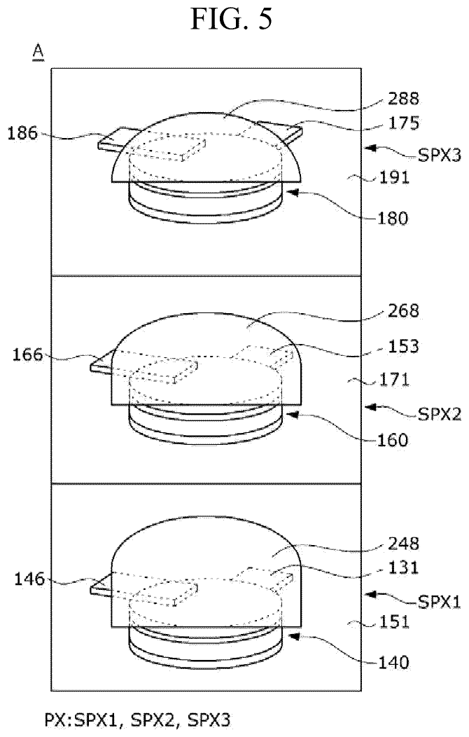

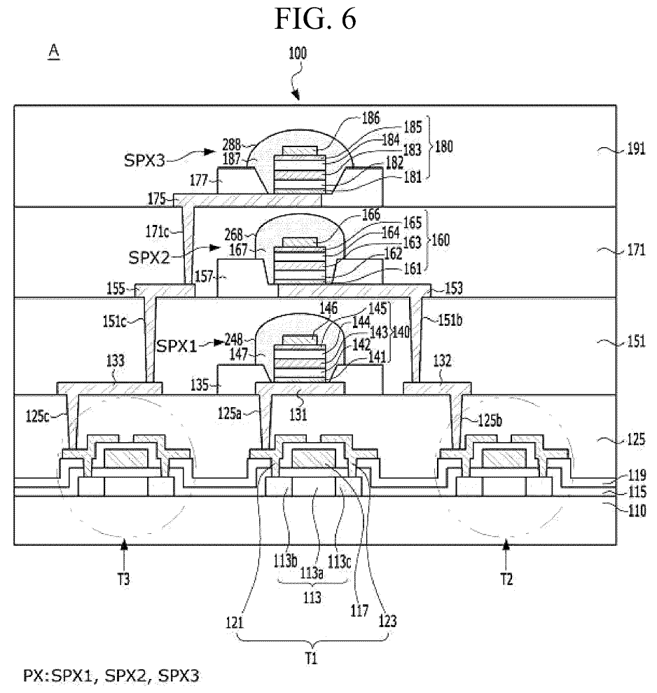

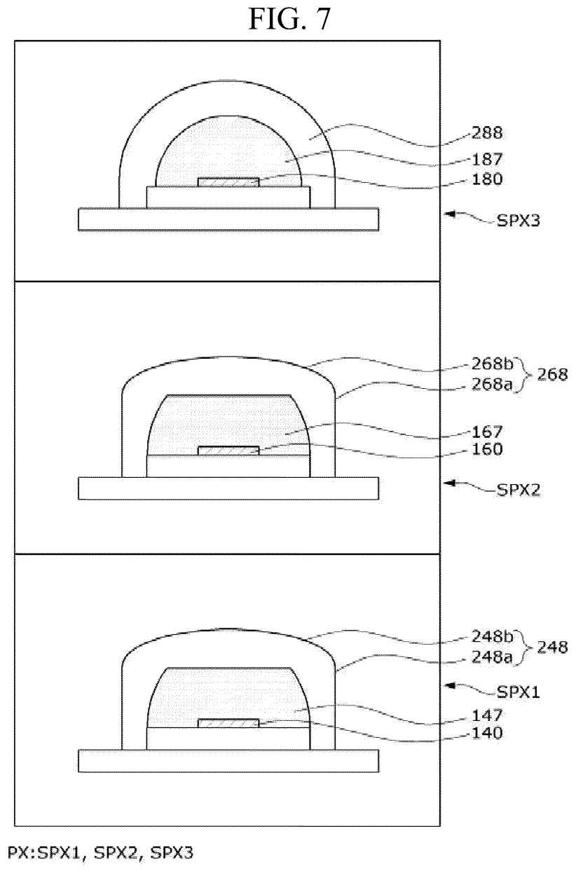

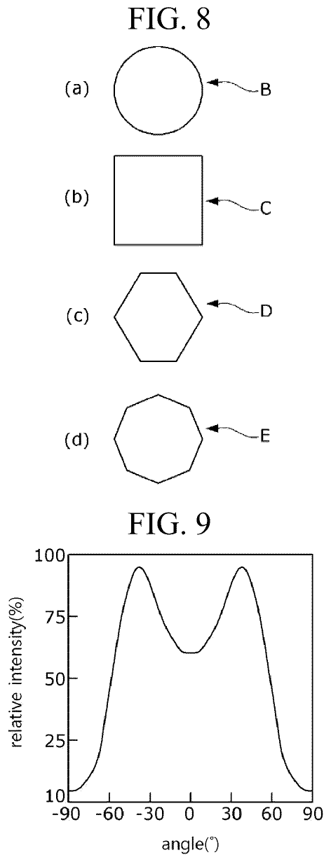

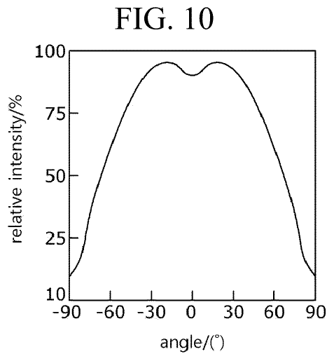

FIG. 5 is an enlarged view of portion A of FIG. 1 in a display device having a lens according to another embodiment of the present specification. FIG. 6 is a cross-sectional view of a display device having a lens according to another embodiment of the present specification. FIG. 7 is a view schematically showing first to third micro-lenses in a display device having a lens according to another embodiment of the present specification. FIG. 8 are views showing planar shapes of first and second micro-lenses in a display device having a lens according to another embodiment of the present specification. FIG. 9 is a view showing characteristics of first and second micro-lenses in a first sub-pixel within a display device having a lens according to another embodiment of the present specification. FIG. 10 is a view showing characteristics of a third micro-lens in a display device having a lens according to another embodiment of the present specification.

In a display device having a vertically stacked structure according to another embodiment of the present specification, except for the structures of the first, second, and third micro-lenses 248, 268, and 288, the remaining components may be the same as those of the display device according to the embodiment of the present specification with reference to FIGS. 1 to 4.

Hereinafter, descriptions of the other components except for the structures of the first, second, and third micro-lenses 248, 268, and 288 will be omitted, and the first, second, and third micro-lenses 248, 268, and 288 will be mainly described with reference to FIGS. 5 to 10.

Referring to FIGS. 5 to 7, each of the pixels PX may include a plurality of sub-pixels SPX having different colors, which are stacked vertically. For example, each of the plurality of pixels PX may be vertically stacked and may include a first sub-pixel SPX1 in which a first light-emitting element 140 emitting light of a red wavelength is disposed, a second sub-pixel SPX2 in which a second light-emitting element 160 emitting light of a green wavelength is disposed, and a third sub-pixel SPX3 in which a third light-emitting element 180 emitting light of a blue wavelength is disposed.

Referring to FIG. 6, in a display device 100 having a vertically stacked structure according to another embodiment of the present specification, a plurality of first, second, and third anode electrodes 131, 153, and 175 may be vertically stacked on a substrate 110.

A plurality of first, second, and third light-emitting elements 140, 160, and 180 may be vertically stacked on the plurality of first, second, and third anode electrodes 131, 153, and 175, respectively.

In addition, first, second, and third transparent resin encapsulants 147, 167, and 187 covering the plurality of first, second, and third light-emitting elements 140, 160, and 180 may be disposed on upper portions of the plurality of first, second, and third light-emitting elements 140, 160, and 180.

First, second, and third micro-lenses 248, 268, and 288 positioned on the upper portions of the plurality of first, second, and third light-emitting elements 140, 160, and 180 may be disposed on the first, second, and third transparent resin encapsulants 147, 167, and 187, respectively.

Referring to FIGS. 5 and 6, the first micro-lens 248 and the second micro-lens 268, which are respectively disposed on the first light-emitting element 140 emitting red light and the second light-emitting element 160 emitting green light, may have a cylindrical lens structure. However, the present specification is not limited thereto.

For example, according to another embodiment of the present specification, a micro-lens structure enabling cylindrical light distribution may be disposed over all of the first light-emitting element 140 emitting red light, the second light-emitting element 160 emitting green light, and the third light-emitting element 180 emitting blue light, or as illustrated in FIGS. 5 and 6, may be disposed only on the first light-emitting element 140 located at the lowermost layer emitting red light and the second light-emitting element 160 located thereon emitting green light.

Specifically, referring to FIGS. 6 and 7, the first micro-lens 248 disposed on the first light-emitting element 140 may include a first side portion 248a and a first upper surface portion 248b. The first side portion 248a may be configured in a cylindrical shape. The first upper surface portion 248b may be configured in a dome type. However, the present specification is not limited thereto.

The second micro-lens 268 may include a second side portion 268a and a second upper surface portion 268b, similar to the first micro-lens 248. The second side portion 268a may be configured in a cylindrical shape, and the second upper surface portion 268b may be configured in a dome type. However, the present specification is not limited thereto. The first micro-lens 248 and the second micro-lens 268 may have the same structure.

Meanwhile, referring to FIG. 8, an upper surface shape of the first and second micro-lenses 248 and 288 may include a circular shape B of (a) of FIG. 8, a square shape C (b) of FIG. 8, a hexagonal shape D of (c) of FIG. 8, and a polygonal shape E of (d) of FIG. 8. However, the present specification is not limited thereto.

Therefore, referring to FIG. 9, in the case of the first and second micro-lenses 248 and 268 having a cylindrical lens structure, the intensity near a viewing angle of about 30 degrees at the side portions of the lenses has a maximum value compared to the central portion thereof, thereby minimizing light obscured by an upper light-emitting element, for example, the third light-emitting element 180 as well as light lost to the sides.

Meanwhile, referring to FIGS. 6 and 7, a third micro-lens 288 having a hemispherical shape may be disposed on the third light-emitting element 180 that is vertically stacked on the second light-emitting element 160 and emits blue light.

Referring to FIG. 10, unlike the first and second micro-lenses 248 and 268 having a cylindrical lens structure, the intensity at the central portion of the third micro-lens 288 has a large value similar to the intensity at the side portions thereof, rather than near a viewing angle of about 30 degrees at the side portions, thereby minimizing light obscured by the uppermost third light-emitting element 180 as well as light lost to the sides.

As described above, in the display device according to another embodiment of the present specification, when a cylindrical lens is applied, the light intensity at the central and outer portions of the light-emitting elements may be controlled to minimize lost light, thereby controlling light obscured by an upper light-emitting element among a plurality of vertically stacked light-emitting elements. That is, by enhancing light extraction while minimizing light obscured by the upper light-emitting element chip through the use of the cylindrical lens, the light extraction efficiency of a micro LEDoS pixel may be maximized.

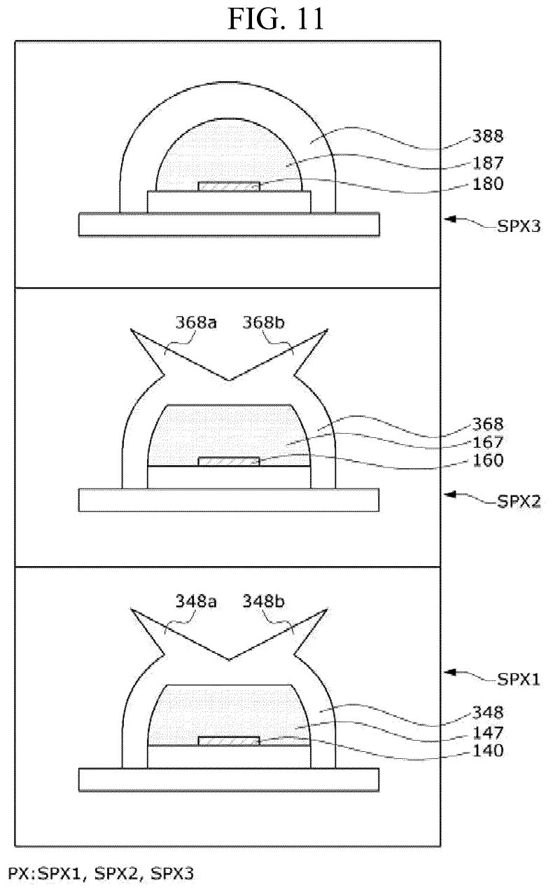

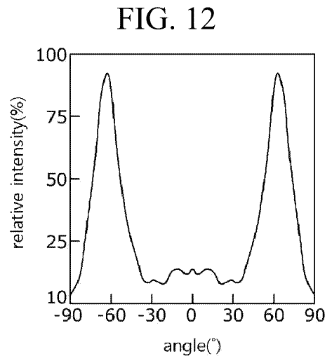

FIG. 11 is a view schematically showing first to third micro-lenses in a display device having a lens according to still another embodiment of the present specification. FIG. 12 is a view showing characteristics of the first and second micro-lenses in the display device having lenses according to still another embodiment of the present specification.

In still another embodiment of the present specification, the cylindrical structure of the first and second micro-lenses 248 and 268 of the embodiment illustrated in FIG. 5 may be replaced with first and second micro-lenses 348 and 368 having a batwing structure. Hereinafter, except for the replacement of the first and second micro-lenses 348 and 368 having a batwing structure, the remaining components are the same as those in the embodiment of FIG. 5, and thus descriptions thereof will be omitted.

Specifically, the following description will focus primarily on the first and second micro-lenses 348 and 368 having a batwing structure, with reference to FIG. 11.

Referring to FIG. 11, the first micro-lens 348 and the second micro-lens 368 respectively disposed on the first light-emitting element 140 emitting red light and the second light-emitting element 160 emitting green light may have a batwing lens structure. However, the present specification is not limited thereto.

Referring to FIG. 11, on both sides of the upper surface of the first micro-lens 348 disposed on the first light-emitting element 140 and having a batwing structure, first-first and first-second batwing portions 348a and 348b, which protrude obliquely upward therefrom, may be provided. In this case, the shapes of the first-first and first-second batwing portions 348a and 348b are not limited thereto.

In addition, on both sides of the upper surface of the second micro-lens 368 disposed on the second light-emitting element 160 vertically stacked on the first light-emitting element 140 and having a batwing structure, second-first and second-second batwing portions 368a and 368b, which protrude obliquely upward therefrom, may be provided. In this case, the second micro-lens 368 may have the same structure as the first micro-lens 348.

Therefore, referring to FIG. 12, in the case of the first and second micro-lenses 348 and 368 having a batwing lens structure, the intensity near a viewing angle of about 60 degrees at the side portions of the lenses is maximized compared to that at the central portion thereof, thereby reducing light obscured by an upper light-emitting element, for example, the third light-emitting element 180 as well as light lost to the sides.

As described above, according to an embodiment of the present specification, when a cylindrical lens is disposed on the light-emitting elements, the light intensity at the central and side portions of the light-emitting elements may be controlled to minimize light lost, thereby controlling light obscured by an upper light-emitting element among a plurality of vertically stacked light-emitting elements.

Therefore, according to the present specification, by enhancing light extraction while minimizing light obscured by the upper light-emitting element chip through the use of the lens, light extraction efficiency of a micro LEDoS pixel may be maximized.

Accordingly, the embodiments disclosed herein are provided for illustrative purposes and are not intended to limit the technical concept of the present specification, and the scope of the technical concept of the present specification is not limited to these embodiments.

Therefore, it should be understood that the embodiments described above are illustrative in all aspects and are not intended to be limiting.

The scope of protection of the present disclosure should be construed on the basis of the following claims, and all technical concepts within the equivalent scope thereof should be construed as falling within the scope of the present specification.

### LIST OF REFERENCE NUMBERS

100: Display device
110: Substrate
113: Active layer
117: Gate electrode
119: Interlayer insulating layer
121: Drain electrode
123: Source electrode
125: First planarization layer
131: First anode electrode
132: Second connection electrode
133: Third-first connection electrode
135: First bank pattern
140: First light-emitting element
141: First-first contact electrode
142: First-first conductive semiconductor layer
143: First light-emitting layer
144: First-second conductive semiconductor layer
145: First-second contact electrode
146: First cathode electrode
147: First transparent resin encapsulant
148: First micro-lens
151: Second planarization layer
153: Second anode electrode
155: Third-second connection electrode
157: Second bank pattern
160: Second light-emitting element
161: Second-first contact electrode
162: Second-first conductive semiconductor layer
163: Second light-emitting layer
164: Second-second conductive semiconductor layer
165: Second-second contact electrode
166: Second cathode electrode
167: Second transparent resin encapsulant
168: Second micro-lens
171: Third planarization layer
175: Third anode electrode
177: Third bank pattern
180: Third light-emitting element
181: Third-first contact electrode
182: Third-first conductive semiconductor layer
183: Third light-emitting layer
184: Third-second conductive semiconductor layer
185: Third-second contact electrode
186: Third cathode electrode
187: Third transparent resin encapsulant
188: Third micro-lens
191: Fourth planarization layer
T1: First thin film transistor
T2: Second thin film transistor
T3: Third thin film transistor
PX: Pixel
SPX1: First sub-pixel
SPX2: Second sub-pixel
SPX3: Third sub-pixel

What is claimed is:

1. A display device comprising:
first, second and third thin film transistors disposed on a substrate;
a first planarization layer disposed on the substrate and covering the first to the third thin film transistors;
a first light-emitting element of a first color disposed on the first planarization layer and connected to the first thin film transistor;
a first micro-lens disposed on the first light-emitting element;
a second planarization layer disposed on the first planarization layer and covering the first micro-lens and the first light-emitting element;
a second light-emitting element of a second color disposed on the second planarization layer and connected to the second thin film transistor;
a second micro-lens disposed on the second light-emitting element;
a third planarization layer disposed on the second planarization layer and covering the second micro-lens and the second light-emitting element;
a third light-emitting element of a third color disposed on the third planarization layer and connected to the third thin film transistor; and
a third micro-lens disposed on the third light-emitting element.

2. The display device of claim 1, wherein a curvature of the first micro-lens is greater than a curvature of the second micro-lens, and the curvature of the second micro-lens is greater than a curvature of the third micro-lens.

3. The display device of claim 1, wherein the first light-emitting element of the first color is a red light-emitting element, the second light-emitting element of the second color is a green light-emitting element, and the third light-emitting element of the third color is a blue light-emitting element.

4. The display device of claim 1, wherein the first to the third light-emitting elements are disposed to vertically overlap one another.

5. The display device of claim 1, wherein the first to the third micro-lenses include a hemispherical shape.

6. The display device of claim 1, wherein the first micro-lens and the second micro-lens include a cylindrical lens or a batwing lens.

7. The display device of claim 6, wherein a planar shape of the first micro-lens and the second micro-lens includes any one of a circular shape, a square shape, a hexagonal shape, and a polygonal shape.

8. The display device of claim 6, wherein the third micro-lens includes a hemispherical shape.

9. The display device of claim 1, wherein:
the first light-emitting element is connected to the first thin film transistor through a first anode electrode disposed on the first planarization layer,
the second light-emitting element is connected to the second thin film transistor through a first connection electrode disposed on the first planarization layer and a second anode electrode disposed on the second planarization layer, and
the third light-emitting element is connected to the third thin film transistor through a first connection electrode disposed on the first planarization layer, a second connection electrode disposed on the second planarization layer, and a third anode electrode disposed on the third planarization layer.

10. The display device of claim 1, further comprising:
a fourth planarization layer disposed on the third planarization layer and covering the third micro-lens and the third light-emitting element.

11. The display device of claim 1, wherein:
a first transparent resin encapsulant is disposed between the first light-emitting element and the first micro-lens,
a second transparent resin encapsulant is disposed between the second light-emitting element and the second micro-lens, and
a third transparent resin encapsulant is disposed between the third light-emitting element and the third micro-lens.
